(19) United States
(12) Patent Application Publication
(10) Pub. No.: US 2008/0007279 A1
(43) Pub. Date: Jan. 10, 2008

(54) Probe Cards

(75) Inventors: David Wood, Durham (GB); Michael Cooke, Durham (GB)

Correspondence Address: DRINKER BIDDLE & REATH;ATTN: INTELLECTUAL PROPERTY GROUP, ONE LOGAN SQUARE, 18TH AND CHERRY STREETS, PHILADELPHIA, PA, 19103-6996, US

(73) Assignee: UNIVERSITY OF DURHAM

(21) Appl. No.: 11/628,681

(22) PCT Filed: Jun. 8, 2005
(86) PCT No.: PCT/GB05/02257

§ 371 Date: Dec. 6, 2006

(30) Foreign Application Priority Data
Jun. 8, 2004 (GB) 04122728.8

(51) Int. Cl. G01R 1/067; G01R 1/073

(52) U.S. Cl. 324/754

(57) ABSTRACT

A probe card for testing IC circuits is provided that comprises a probe member for each IC contact that comprises a flexible membrane structure secured at two points to a reverse surface of a substrate. A contact means can also be provided, which can be a probe bump or a specially shaped recess. Force limiting means can be provided so that the force applied can be controlled and damage of the IC to be tested can be limited.

The present invention relates to improvements in or relating to probe cards, and in particular to a novel probe member used in a probe card.

In the context of the present invention, a “probe card” is taken to mean a device that interfaces with the electrical contacts of an integrated circuit (IC) in order to test the proper functioning of the IC.

A known probe card is a piece of precision mechanical engineering. It comprises a base member on which a printed circuit is formed, together with a large number of individually assembled probe members usually arranged either in a circular or a rectangular perimeter around a space where the chip to be tested will sit.

The probe members are thin metallic cantilever members having a first end attached to the reverse surface of the probe card and a free end which is for making contact with the electrical contact of an IC. Probe members of this type are tapered so that their tips have predetermined surface areas and/or profiles, and are usually bent to a predetermined angle, according to the application.

When a probe card is lowered onto an IC, the tips of the probe members come into contact with the IC's electrical contact pads. The probe members flex when they touch the wafer and slide across the surface of the IC contact pads, removing a layer of oxide on the surface. This improves electrical contact between the IC and the probe member, which increases the accuracy of the testing process. However, the damage done to the IC due to the removal of the oxide layer can be a serious inconvenience. Furthermore, it is hard to control the force applied to the IC by the probe card, and if the force applied gets too large then the oxide layer and further embedded circuitry or other IC components may be damaged.

Known probes are individually addressable electrically and have all to be assembled and set at the same correct height on the probe card in order to function. The complete card takes a long time to assemble and is large and expensive.

Accordingly, there is a need for a probe card which is cheaper to produce and which causes less damage to an integrated circuit that it tests.

According to the present invention there is provided a probe card comprising a base member and a plurality of probe members, characterised in that each of said probe members is anchored at at least two points to the reverse surface of the base member.

Preferably, the probe member comprises contact means for contacting a contact pad of an IC to be tested. Preferably, one probe member is provided for each contact pad of an IC to be tested.

Preferably, the probe members comprise a flexible membrane.

Preferably, the membrane structure is electroplated.

Preferably, for certain applications, the contact means comprises a protrusion provided at a central portion of the probe member.

Preferably, for other applications, the contact means comprises a recess formed within a central portion of the probe member.

Preferably, the recess is of a shape to urge an IC bump towards a central point of the recess when the probe card is brought into contact with an IC to be tested.

Preferably, the probe card further comprises force limiting means.

Preferably, the force limiting means comprises an abutment from the reverse surface of the probe card, located behind the probe member.

Preferably, the probe member is bridge shaped.

Preferably, the probe member is T-shaped.

According to a second aspect of the present invention, there is provided a method of fabricating a probe card comprising the step of forming a probe member on a seed layer with e-beam evaporation and photolithography.

The present invention will now be described, by way of example only, with reference to the accompanying drawings, in which:

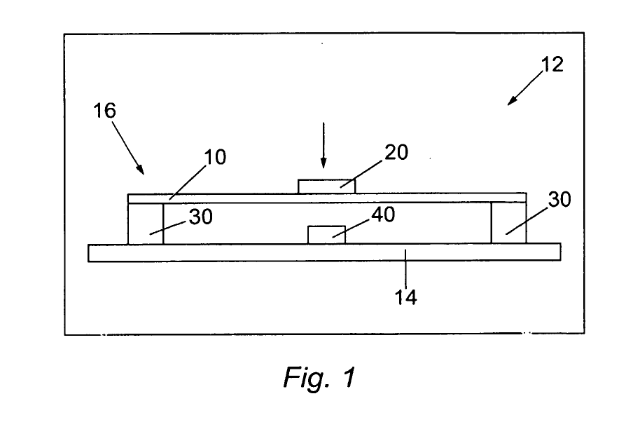

FIG. 1 shows a probe card according to a first embodiment;

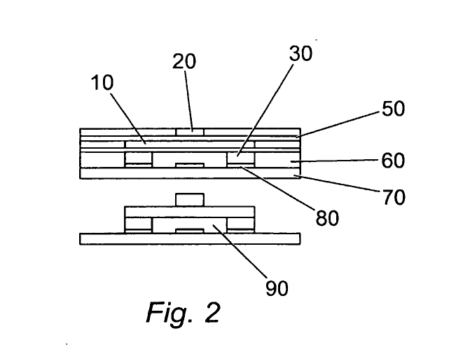

FIG. 2 illustrates the process of manufacture of the probe card of FIG. 1;

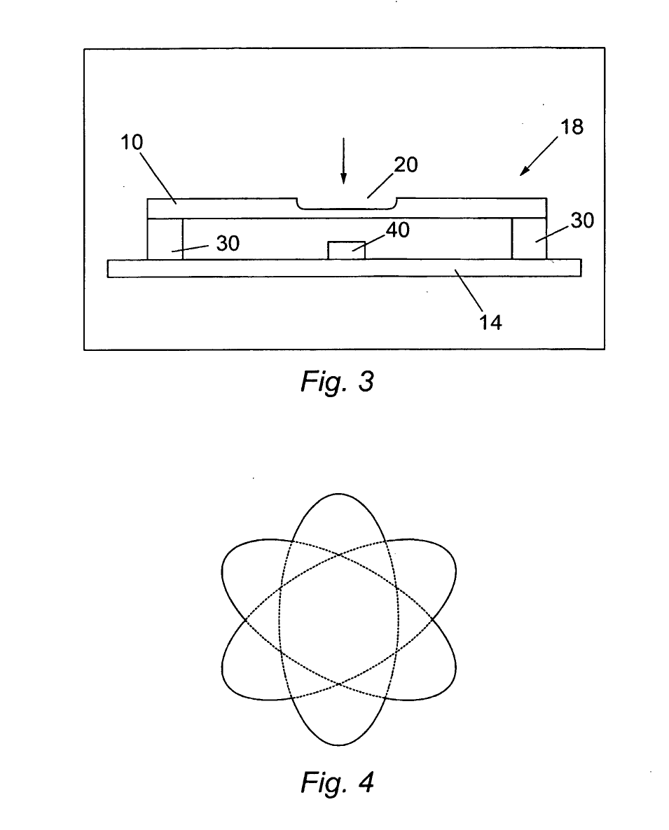

FIG. 3 shows a probe card according to a second embodiment;

FIG. 4 illustrates the design of a contact means formed in the probe card of FIG. 3; and

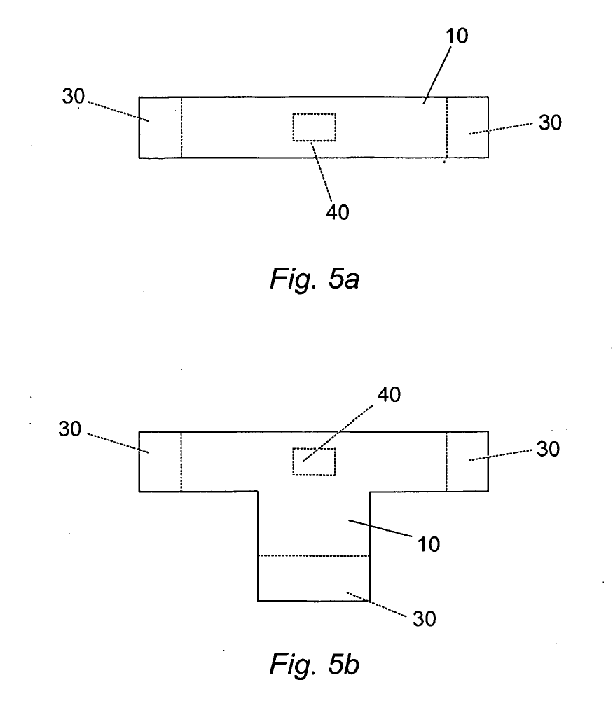

FIGS. 5a and 5b illustrate two possible embodiments of a probe member suitable for use with any of the probe cards of FIGS. 1 and 3.

FIG. 1 shows a probe card 12 according to a first embodiment of the invention. A printed circuit board can be formed on either face of a base member 14. A probe member 16 is formed on the reverse surface of the base member 14 and comprises an electroplated membrane 10 supported by anchor members 30, and, optionally, contact means 20 for engaging with the electrical contacts of an IC to be tested. Where no dedicated contact means are provided, the membrane itself can form an electrical connection with the IC's electrical contact pads.

In the context of the invention, the term “membrane” can be taken to refer to any thin, pliable material. The electroplated membrane 10 can take any shape, so long as it is anchored at more than one point on the reverse surface of the base member 14. In one example embodiment, the electroplated membrane 10 is in the shape of a bridge (that is, a rectangle having a length greater than its width) with the anchor members 30 being provided at either end thereof. This is illustrated in FIG. 5a. In a second example embodiment, the electroplated membrane 10 has a T shape with anchor members 30 being provided at each lug thereof, as illustrated in FIG. 5b.

Contact means 20 is provided on the electroplated membrane 10 for abutment with the electrical contact of an IC which is to be tested. In the example probe member 12 shown in FIG. 1, the contact means 20 comprises an electroplated probe bump.

An optional force limiting means 40 is provided below the electroplated membrane 10 to allow control of the force applied during a testing process. The direction of the applied force is shown by the arrow in FIG. 1.

FIG. 2 illustrates the process by which the probe card 12 of FIG. 1 is constructed. The anchor members 30 and force limiting means 40 are fabricated using e-beam evaporated metal on a seed layer 50, which is photo-lithographically patterned and wet etched. A sacrificial layer 60 is also added to reduce the static friction problems. The membrane 10, probe bump 20 and anchor members 30 are also defined by photolithography and fabricated using standard electroplating techniques.

It is to be understood that components of the probe card 12 can be fabricated from a number of different conducting materials. The choice of metals is limited only by the adhesion characteristics during processing.

The size of the membrane 10 is primarily determined by device fabrication considerations. The larger the membrane 10 area, the greater the associated problems with static friction are found in the finished device. Furthermore, an increase in the membrane area decreases the number of probe members that can be formed on a single probe card. However, too small a structure increases the stress in the membrane 10 during deflection and limits the use of the force limiting means 40. Actual dimensions are application specific and can range for example 1 mm by 1 mm down to less than 100 microns by 100 microns. Membrane thickness also depends on the required application and the required electrical characteristics of the probe card.

In order to test an IC, the probe card is brought into contact with the IC such that the contact means 20 abuts an electrical contact of the IC. As the probe card 12 is urged towards the IC, force is applied in the direction of the arrow shown in FIG. 1 and the membrane 10 flexes, the centre of the membrane moving downwards as shown in the figures. The amount of flex is related to the force that is applied and this is limited mechanically by the force limiting means 40.

Before the probe card 12 is used, there is no electrical conduction between the probe bump 20 and the force limiting means 40. However, there is electrical conduction when they contact each other and so the force applied can be accurately measured and controlled. The force limiting means 40 can easily detect when the membrane is touching it, and therefore can be used to give feedback on the force applied to the probe.

This helps reduce the amount of damage that can be done to the IC being tested. In a prior art cantilever type probe member, the flexion of the probe member results in a scrubbing motion across the oxide film of the IC. However, because it is fixed at more than one point to the reverse surface of the base member 14, the probe member 16 does not move across the surface of the IC as it is urged into contact therewith, therefore avoiding the known scrubbing motion.

Thus, the risk of damage to the IC is minimised. Furthermore, the lifetime of the card itself 12 is increased with respect to a card comprising cantilever type probe members, and the probe card 12 can go through a testing cycle repeatedly without damage.

The addition of the probe bump 20 increases the deflection of the membrane when it is used to contact a contact pad of an IC.

The functioning of a circuit which can for example be formed on the base member 14 in order to analyse the signals received by the probe members 16 is well known per se, and will not be described in more detail herein.

FIG. 3 illustrates a second embodiment of the present invention. Probe card 18 comprises a electroplated membrane 10, anchor members 30 and force limiting means 40 formed on a base member 14, all as in FIG. 1. Contact means 20 is provided on the membrane 10. However, in this embodiment the contact means 20 comprises a recess within the membrane. This embodiment is used when the contact pads of an IC comprise soldered bumps.

Registration of the IC bumps with the probe card's membrane 10 can be further improved by forming the recess in a particular shape that urges a bump to register with a central point in the recess. An example recess shape is shown in FIG. 4, which can be understood as being formed from the combination of three semi-ellipsoids hollowed out of the surface of the membrane. When an IC bump makes contact with one end of a notional ellipsoid, it is entrained and further force applied to urge the probe card 18 and IC to be tested together causes the IC bump to move towards the centre of the illustrated shape.

The design of a probe member according to any embodiment results in a probe member that is much more durable than any previously known probe members. Furthermore, the probe member structure means that a probe card comprising a large array of members can be manufactured.

The electroplated design is particularly durable for industrial applications, with multiple cycles showing no damage to the structure. The low contact resistance of the new probe card is consistent with that found in more complex structures, i.e. is less than 0.5 Ohms. The structures have the potential for mass manufacturing in large arrays at relatively low production costs. It is also to be appreciated that the modification between embodiments of FIGS. 1 and 3 can be easily performed during the design phase.

Another advantage is that, because a probe member can be provided for each IC electrical contact, the probe card can be fully customised to account for any varying heights in the IC contacts.

Various improvements and modifications can be made to the above departing from the scope of the invention.

1. A probe card comprising a base member and a plurality of probe members, characterized in that each of said probe members is anchored at at least two points to the reverse surface of the base member.

2. The probe card of claim 1, wherein the probe member comprises contact means for contacting a contact pad of an IC to be tested.

3. The probe card of claim 1, wherein one probe member is provided for each contact pad of an IC to be tested.

4. The probe card of claim 1, wherein the probe member comprises a flexible membrane.

5. The probe card of claim 4, wherein the membrane structure is electroplated.

6. The probe card of claim 1, wherein the contact means comprises a protrusion provided at a central portion of the probe member.

7. The probe card of claim 1, wherein the contact means comprises a recess formed within a central portion of the probe member.

8. The probe card of claim 7, wherein the recess is of a shape to urge an IC bump towards a central point of the recess when the probe card is brought into contact with an IC to be tested.

9. The probe card of claim 1, wherein the probe card further comprises force limiting means.

10. The probe card of claim 9, wherein the force limiting means comprises an abutment from the reverse surface of the probe card, located behind the probe member.

11. The probe card of claim 1, comprising at least one bridge shaped probe member.

12. The probe card of claim 1, comprising at least one T-shaped probe member.

13. A method of fabricating a probe card comprising the step of forming a probe member on a seed layer with e-beam evaporation and photolithography.

14. The method of claim 13, wherein the probe card comprises a base member and a plurality of probe members, characterized in that each of said probe members is anchored at at least two points to the reverse surface of the base member.
